(19) United States
(12) Patent Application Publication
(10) Pub. No.: US 2019/0092620 A1
(43) Pub. Date: Mar. 28, 2019

(54) PHYSICAL QUANTITY SENSOR

(71) Applicant: DENSO CORPORATION, Kariya-city (JP)

(72) Inventor: Tomoya JOMORI, Kariya-city (JP)

(21) Appl. No.: 16/202,162

(22) Filed: Nov. 28, 2018

Related U.S. Application Data
(63) Continuation of application No. PCT/JP2017/023191, filed on Jun. 23, 2017.

(30) Foreign Application Priority Data
Jul. 1, 2016 (JP) 2016-131788

(51) Int. Cl. B81B 3/00; G01P 3/22; G01C 19/5747

(52) U.S. Cl. CPC B81B 3/0045; B81B 2201/0242; G01C 19/5747; G01P 3/22

(57) ABSTRACT

A physical quantity sensor includes a substrate, a beam part that includes a detection beam, a detection weight that is supported on the substrate through the beam part, and a detection piezoelectric film that is disposed on the detection beam and is configured to generate an electric output according to displacement of the detection beam caused by movement of the detection weight in a direction due to an application of a physical quantity. The detection beam includes a first detection beam and a second detection beam that are disposed to hold the detection weight at different positions from each other in the direction. The first detection beam and the second detection beam have different spring constants, and the detection piezoelectric film is disposed on the first detection beam.

### CROSS REFERENCE TO RELATED APPLICATIONS

The present application is a continuation application of International Patent Application No. PCT/JP2017/023191 filed on Jun. 23, 2017, which designated the U.S. and claims the benefit of priority from Japanese Patent Application No. 2016-131788 filed on Jul. 1, 2016. The entire disclosures of all of the above applications are incorporated herein by reference.

### TECHNICAL FIELD

The present disclosure relates to a physical quantity sensor.

### BACKGROUND

A physical quantity sensor has a detection weight that is supported by a spring to be displaceable in accordance with an applied physical quantity. The physical quantity sensor detects the physical quantity based on the amount of displacement of the detection weight. The physical quantity sensor is for example used for an angular velocity sensor, an acceleration sensor and the like. As an example of the physical quantity sensor, a gyro sensor has been known. The gyro sensor has a drive weight that is vibrated in a planar direction of a substrate, and a detection weight connected to the drive weight through a detection spring. When the gyro sensor is applied with an angular velocity while the drive weight is driven and vibrated in a predetermined direction, the detection weight is vibrated in a direction intersecting with the predetermined direction. Thus, the gyro sensor detects the angular velocity.

### SUMMARY

The present disclosure provides a physical quantity sensor including a substrate; a detection weight that is supported to the substrate through a beam part including a detection beam; a detection piezoelectric film that is disposed on the detection beam and is configured to generate an electric output, when the detection weight moves in a direction in accordance with an application of a physical quantity, according to a displacement of the detection beam with the movement of the detection weight. The detection beam includes a first detection beam and a second detection beam. The first detection beam and the second detection beam are disposed to hold the detection weight at positions different from each other in the direction. The first detection beam and the second detection beam have different spring constants, and the detection piezoelectric film is disposed on the first detection beam.

### BRIEF DESCRIPTION OF DRAWINGS

The above and other objects, features and advantages of the present disclosure will become more apparent from the following detailed description made with reference to the accompanying drawings, in which like parts are designated by like reference numbers and in which:

FIG. 1 is a diagram illustrating a schematic plan view of a vibration type angular velocity sensor according to an embodiment of the present disclosure;

FIG. 2 is a diagram illustrating a state of the vibration type angular velocity sensor in a regular operation;

FIG. 3 is a diagram illustrating a state of the vibration type angular velocity sensor when being applied with an angular velocity;

FIG. 4 is a diagram illustrating an enlarged view of a first detection beam being displaced due to the application of the angular velocity in FIG. 3;

FIG. 5A is a diagram illustrating a spring configuration having the first detection beam, but without having a second detection beam; and

FIG. 5B is a diagram illustrating a spring configuration having both of the first detection beam and the second detection beam.

### DETAILED DESCRIPTION

In a physical quantity sensor having a drive weight vibrated in a planar direction of a substrate, and a detection weight connected to the drive weight through a detection spring, a beam is likely to be thinned in consideration of sensitivity and impact resistance. As the physical quantity sensor, there are an electrostatic capacitance type which outputs the displacement of the detection weight as a capacitance, and a piezoelectric type which outputs the displacement of the detection weight as a piezoelectric change. In the case of the piezoelectric type, however, if a piezoelectric film is formed on a thinned beam, the area for the piezoelectric film is reduced. As a result, it is difficult to obtain a desired sensitivity. On the other hand, if the beam is thicken in order to secure the area for forming the piezoelectric film, the rigidity of the beam is increased. As a result, the resonance frequency of the detection weight at the time of application of the physical quantity is increased, and the sensitivity is adversely decreased. Namely, it is difficult to improve the sensitivity only by thickening the beams.

In an embodiment of the present disclosure, the physical quantity sensor includes: a substrate; a beam part that includes a detection beam; a detection weight that is supported to the substrate through the beam part; and a detection piezoelectric film that is disposed on the detection beam and is configured to generate an electric output, when the detection weight moves in a direction in accordance with an application of a physical quantity, according to a displacement of the detection beam with the movement of the detection weight. The detection beam includes a first detection beam and a second detection beam. The first detection beam and the second detection beam are disposed to hold the detection weight at positions different from each other in the direction. The first detection beam and the second detection beam have different spring constants. The detection piezoelectric film is disposed on the first detection beam.

In the case where the first detection beam and the second detection beam have different spring constants, for example, the dimension of one of the first detection beam and the second detection beam can be made larger than the other. Alternatively, since the rigidity of one of the first detection beam and the second beam can be made smaller than the other, the first detection beam and the second detection beam can be made into the same dimension. In such a case the dimension can be increased, as compared with the case where both of the first detection beam and the second detection beam are made with a material having a high rigidity. Thus, the formation area for the detection piezoelectric film can be increased. In addition, an increase in detection resonance frequency can be reduced. Accordingly, it is possible to improve the sensitivity.

Hereinafter, embodiments of the present disclosure will be described more in detail with reference to the drawings. In the following descriptions, the same or equivalent parts are designated with the same reference numerals in the respective embodiments.

### First Embodiment

A first embodiment of the present disclosure will be described. In the present embodiment, a vibration type angular velocity sensor, which is so-called a gyro sensor, will be described as an example of the physical quantity sensor.

The vibration type angular velocity sensor described in the present embodiment is a sensor for detecting an angular velocity as a physical quantity and is used for detecting a rotational angular velocity about a center line parallel to the vertical direction of a vehicle, for example. However, the vibration type angular velocity sensor can be used for any other purposes other than for vehicles.

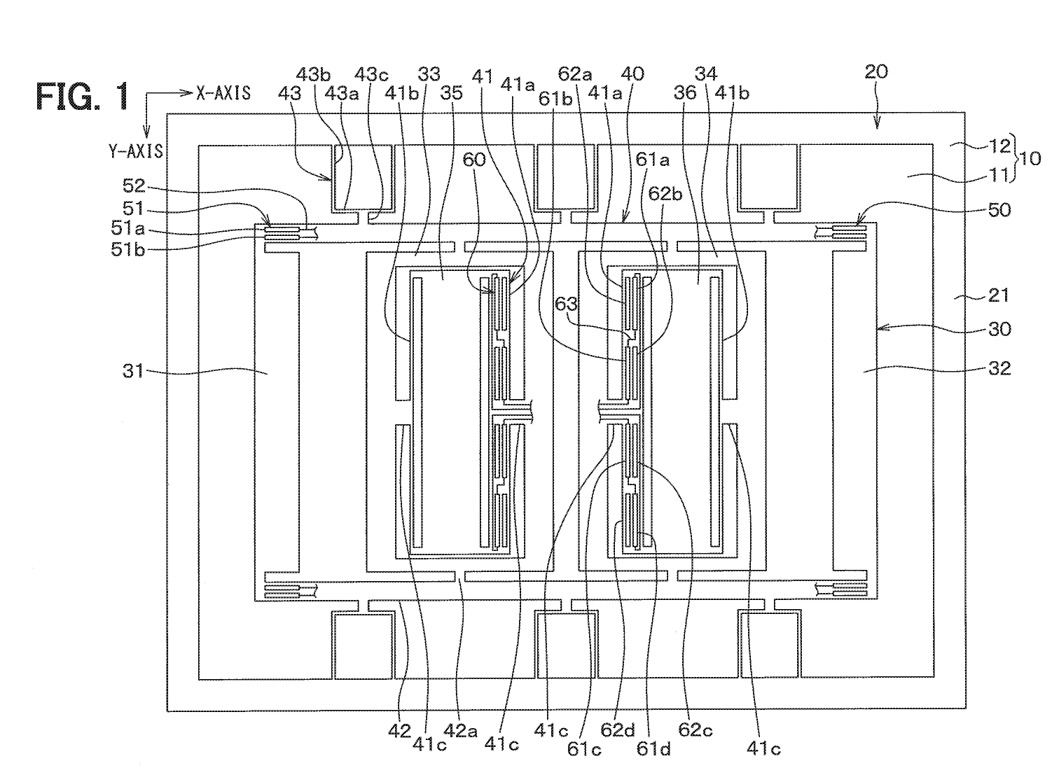

FIG. 1 is a diagram illustrating a schematic plan view of a vibration type angular velocity sensor according to the present embodiment. The vibration type angular velocity sensor is mounted on the vehicle in such a manner that the direction of the normal line of the paper of FIG. 1 coincides with the vertical direction of the vehicle.

The vibration type angular velocity sensor is formed at a surface of a plate-shaped substrate 10 on one side. The substrate 10 is provided by an SOI (Silicon on Insulator) substrate having a structure in which a buried oxide film to be a sacrifice layer (not shown) is interposed between a support substrate 11 and a semiconductor layer 12. Such a sensor structure is formed by partially removing the buried oxide film after etching the substrate 10 on a side adjacent to the semiconductor layer 12 into the pattern of the sensor structure, so that a part of the sensor structure is made into a released state.

Note that, in the following descriptions, a direction that is included in a plane parallel to the surface of the semiconductor layer 12 and is in a left and right direction in the paper of FIG. 1 will be referred to as an X-axis direction, and a direction that is orthogonal to the X-axis direction and in the up and down direction of the paper of FIG. 1 is referred to as a Y-axis direction. Further, a direction that is orthogonal to the surface of the semiconductor layer 12 will be referred to as a Z-axis direction.

The semiconductor layer 12 is patterned into a fixed part 20, a movable part 30, and a beam part 40. The fixed part 20 has a buried oxide film left at least at a part of the back surface thereof and is not released from the support substrate 11. The fixed part 20 is fixed to the support substrate 11 via the buried oxide film. The movable part 30 and the beam part 40 constitute a vibrator in the vibration type angular velocity sensor. In the movable part 30, the buried oxide film is removed from the back surface thereof. The movable part 30 is in a state of being released from the support substrate 11. The beam part 40 supports the movable part 30 and allows the movable part 30 to displace in the X-axis direction and the Y-axis direction in order to detect an angular velocity. Specific structures of the fixed part 20, the movable part 30, and the beam part 40 will be described.

The fixed part 20 is configured to have a support fixing portion 21 for supporting the movable part 30.

The support fixing portion 21 is disposed so as to surround the periphery of a sensor structure such as the movable part 30 and the beam part 40, and supports the movable part 30 via the beam part 40 on inner wall surfaces of the support fixing portion 21. In the present embodiment, the support fixing portion 21 exemplarily supports the entire periphery of the sensor structure body. However, the support fixing portion 21 may be formed only at a part of the periphery of the sensor structure body. In this case, the fixed part 20 exemplarily has only the support fixing portion 21. Alternatively, the fixed part 20 may further have another fixing portion, such as a pad-fixing portion onto which a pad (not shown) is to be formed.

The movable part 30 displaces in accordance with the application of an angular velocity. The movable part 30 includes outer driving weights 31 and 32, the inner driving weights 33 and 34 and detection weights 35 and 36. The movable part 30 has a layout in which the outer driving weight 31, the inner driving weight 33 provided with the detection weight 35, the inner driving weight 34 provided with the detection weight 36, and the outer driving weight 32 are arranged in the X-axis direction in order. Namely, the two inner driving weights 33 and 34, respectively, having the detection weights 35 and 36 therein are arranged on an inner region, and the outer driving weights 31 and 32 are arranged on both sides of the two inner driving weights 33 and 34 such that the two inner driving weights 33 and 34 are interposed between the two outer driving weights 31 and 32.

The outer driving weights 31 and 32 are extended in the Y-axis direction. The outer driving weight 31 is disposed to face the inner driving weight 33, and the outer driving weight 32 is disposed to face the inner driving weight 34. These outer driving weights 31 and 32 function as a mass portion. The outer driving weights 31 and 32 are thicker than each of beams of the beam part 40. The outer driving weights 31 and 32 are movable in the Y-axis direction when drive vibration for detection is performed.

The inner driving weights 33 and 34 each have a quadrangular frame shape. These inner driving weights 33 and 34 function as the mass portion. The inner driving weights 33 and 34 are thicker than each of the beams of the beam part 40, and are movable in the Y-axis direction. Each of the inner driving weights 33 and 34 having the quadrangular shape includes a pair of sides opposed to each other and parallel in the X-axis direction and a pair of sides opposed to each other and in parallel in the Y-axis direction. Of the pair of parallel sides of each of the inner driving weights 33 and 34 extended in the Y-axis direction, one is arranged to oppose the outer driving weight 31 or 32, and the other is arranged to oppose to the adjacent outer driving weight 33 or 34.

The detection weights 35 and 36 each have a quadrangular shape. The detection weights 35 and 36 are supported on the inner wall surfaces of the inner driving weights 33, 34 via detection beams 41 of the beam part 40, which will be described later. The detection weights 35 and 36 also function as the mass portion, and are moved in the Y-axis direction together with the inner driving weights 33 and 34 by performing the drive vibration. However, the detection weights 35 and 36 are moved in the X-axis direction when an angular velocity is applied.

The beam part 40 includes the detection beams 41, driving beams 42, and support members 43.

Each of the detection beams 41 connects between an inner wall surface of the side of the inner driving weight 33, 34 and an outer wall surface of the side of the detection weight 35, 36, the sides being extended in the Y-axis direction in parallel. In the present embodiment, the detection beam 41 is a beam of a double-side supporting structure that supports the detection weight 35, 36 at different positions in the X-axis direction. More specifically, the detection beam 41 is disposed on both sides of each of the detection weights 35, 36 in the X-axis direction, one of which serves as the first detection beam 41a and the other as the second detection beam 41b. Thus, the detection beam 41 supports the detection weight 35, 36 on both sides in the X-axis direction. The first detection beam 41a and the second detection beam 41b are connected to the inner wall surfaces of the inner driving weight 33, 34 through the connection portions 41c provided at the center of the first and second detection beams 41a and 41b in the Y-axis direction. The detection beam 41 supports the detection weight 35, 36 at both ends in the Y-axis direction, on opposite sides with respect to the connection portions 41c.

In such a configuration, since the detection beam 41 has a shape along the Y-axis direction, the detection beam 41 can be displaced in the X-axis direction. Due to the displacement of the detection beam 41 in the X-axis direction, the detection weights 35 and 36 are allowed to move in the X-axis direction.

Further, the spring constant of the first detection beam 41a and the spring constant of the second detection beam 41b have different values. In the present embodiment, since the first detection beam 41a and the second detection beam 41b are both formed by patterning the semiconductor layer 12, the first detection beam 41a and the second detection beam 41b are made of the same material. For this reason, the dimension of the first detection beam 41a and the dimension of the second detection beam 41b are differentiated in the X-axis direction. With such a configuration, the spring constant of the first detection beam 41a and the spring constant of the second detection beam 41 b have different values.

More specifically, the first detection beam 41a is provided adjacent to an inner side of each of the detection weights 35 and 36. Namely, the first detection beam 41a is provided on a side of the detection weight 35, the side being adjacent to the detection weight 36. The first detection beam 41a is also provided on a side of the detection weight 36, the side being adjacent to the detection weight 35. The second detection beam 41b is provided opposite to the first detection beam 41a with respect to each of the detection weights 35 and 36. Further, the dimension of the first detection beam 41a in the X-axis direction is larger than that of the second detection beam 41b, so that the first detection beam 41a has a larger spring constant than the second detection beam 41b.

The driving beams 42 connect the outer driving weights 31 and 32 and the inner driving weights 33 and 34, and allow the outer driving weights 31 and 32 and the inner driving weights 33 and 34 to move in the Y-axis direction. The outer driving weight 31, the inner driving weight 33, the outer driving weight 34 and the outer driving weight 32 are arranged in this order, and are connected to each other through the driving beam 42 in that arranged state.

Specifically, the driving beam 42 has a straight shaped beam having a predetermined dimension as a width in the Y-axis direction. The driving beams 42 are arranged on both sides of the arrangement of the outer driving weights 31 and 32 and the inner driving weights 33 and 34 in the Y-axis direction. The driving beams 42 are connected to the outer driving weights 31 and 32 and the inner driving weights 33 and 34. The driving beams 42 may be directly connected to the outer driving weights 31 and 32 and the inner driving weights 33 and 34. In the present embodiment, however, the driving beams 42 and the inner driving weights 33 and 34 are connected via connection portions 42a.

The support members 43 support the outer driving weights 31 and 32, the inner driving weights 33 and 34 and the detection weights 35 and 36. Specifically, the support members 43 are provided between the inner wall surface of the support fixing portion 21 and the driving beams 42. The support members 43 support the respective weights 31 to 36 to the support fixing portion 21 via the driving beams 42.

The support member 43 has a structure including a rotation beam 43a, a supporting beam 43b, and a connection portion 43c. The rotation beam 43a is a linear beam having a predetermined width in the Y-axis direction. The supporting beams 43b are connected to the opposite ends of the rotating beam 43a. Further, the connection portion 43c is connected to the center portion of the rotation beam 43a on a side opposite to the supporting beams 43b. When the sensor is driven, the rotation beam 43a waves and bends in an S shape around the connecting portion 43c. The supporting beams 43b connect the both ends of the rotation beam 43a to the support fixing portion 21. In the present embodiment, the supporting beams 43b are linear members. Also, the supporting beams 43b allow the respective weights 31 to 36 to move in the X-axis direction when an impact or the like is applied thereto. The connection portion 43c has a function of connecting the support member 43 to the driving beam 42.

The vibration type angular velocity sensor is further provided with a drive unit 50 and a detection unit 60.

The drive unit 50 drives and vibrates the sensor structure body such as the movable part 30 and the beam part 40, Specifically, the drive unit 50 includes driving piezoelectric films 51 and driving wirings 52, and the like, which are provided at both ends of each of the driving beams 42.

The driving piezoelectric films 51 are each made of lead zirconate titanate (PZT) thin film or the like, and generate a force for driving and vibrating the sensor structure body when applied with a driving voltage through the driving wiring 52. Two driving piezoelectric films 51 are provided on each end of each driving beam 42. One of the two driving piezoelectric films 51 being adjacent to an outer edge of the sensor structure body is referred to as an outer piezoelectric film 51a and the other being located on an inner side than the outer piezoelectric film 51a is referred to as an inner piezoelectric film 51b. The outer piezoelectric film 51a and the inner piezoelectric film 51b are extended in the X-axis direction, and are arranged in parallel to each other at each arrangement place.

The driving wirings 52 are wirings for applying drive voltages to the outer piezoelectric film 51a and the inner pressure film 51b. In the drawing, only a part of each driving wiring 52 is shown. However, the driving wirings 52 actually extend from the rotation beams 42 to the fixed part 20 through the support members 43. Further, the driving wirings 52 are electrically connected to the outside via pads (not shown) formed on the fixed part 20 by wire bonding or the like. Thus, the drive voltages can be applied to the outer piezoelectric film 51a and the inner piezoelectric film 51b through the driving wirings 52.

The detection unit 60 outputs the displacement of the detection beam 41, as an electric signal, in accordance with the application of the angular velocity. In the present embodiment, the detection unit 60 is formed on the first detection beam 41a, which has a larger spring constant, of the detection beam 41. The detection unit 60 includes detection piezoelectric films 61a to 61d, dummy piezoelectric films 62a to 62d, and detection wirings 63.

The detection piezoelectric films 61a to 61d are formed of PZT thin films or the like. The detection piezoelectric films 61a to 61d are formed in the first detection beam 41a at positions to which tensile stress is applied when the first detection beam 41a is displaced by the application of an angular velocity. Specifically, the piezoelectric films 61a to 61d are formed on sides adjacent to the detection weights 35 and 36 at both ends of the first detection beam 41a, and on sides away from the detection weights 35 and 36 in the X-axis direction in regions adjacent to the connection portion 41c.

The dummy piezoelectric films 62a to 62d are made of PZT thin films or the like. The dummy piezoelectric films 62a to 62d are disposed symmetrically with the detection piezoelectric films 61a to 61d in order to maintain the symmetry of the detection beam 41. That is, the dummy piezoelectric films 62a to 62d are formed in the first detection beams 41a at positions to which compressive stress is applied when the first detection beam 41a is displaced by the application of the angular velocity. Specifically, at both ends of the first detection beam 41a, the dummy piezoelectric films 62a to 62d are arranged on sides away from the detection weights 35 and 36 in the X-axis direction. In the regions adjacent to the connection portion 41c, the dummy piezoelectric films 62a to 62d are located on sides adjacent to the detection weights 35 and 36 in the X-axis direction.

The detection piezoelectric films 61a to 61d and the dummy piezoelectric films 62a to 62d are both extended in the Y-axis direction, and are formed in parallel at respective arrangement places. In the described example, the detection piezoelectric films 61a to 61d are formed at positions at which the tensile stress causing the largest displacement is generated. As another example, the detection piezoelectric films 61a to 61d may be formed at positions at which compressive stress is generated. As further another example, the detection piezoelectric films 61a to 61d may be formed at both positions where the tensile stress is generated and where the compressive stress is generated. In addition, the dummy piezoelectric films 62a to 62d are not always necessary as long as at least the detection piezoelectric films 61a to 61d are formed.

The detection wirings 63 are connected to the detection piezoelectric films 61a to 61d to extract the electric outputs of the detection piezoelectric films 61a to 61d in accordance with the displacement of the detection beams 41. In the drawing, only a part of the detection wiring 63 is shown. However, the detection wirings 63 are actually extended from the inner driving weights 33 and 34 and the driving beams 42 to the fixed part 20 through the support members 43. Further, the detection wirings 63 are electrically connected to the outside by wire bonding or the like via pads (not shown) formed in the fixed part 20. Accordingly, changes in the electric outputs of the detection piezoelectric films 61a to 61d can be transmitted to the outside through the detection wirings 63.

As described above, the vibration type angular velocity sensor is configured to have a pair of angular velocity detecting structures provided with the two outer driving weights 31 and 32, the inner driving weights 33 and 34, and the two detection weights 35 and 36. In the vibration type angular velocity sensor configured as described above, desired sensitivity can be obtained as described later.

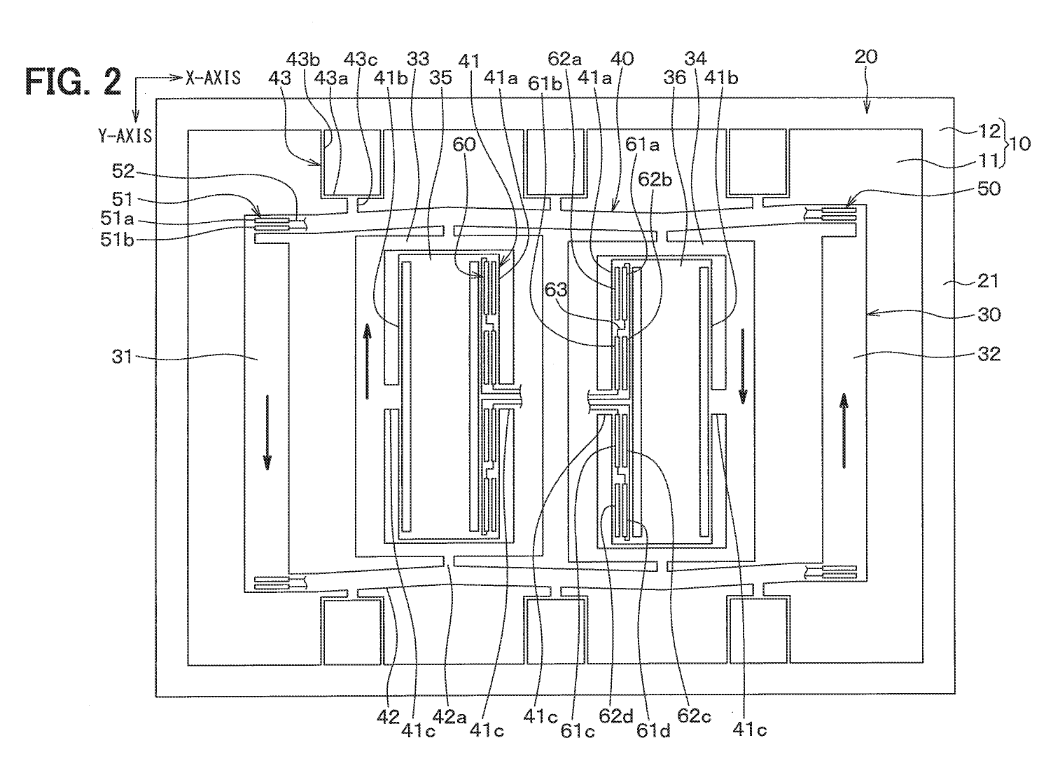

Next, the operation of the vibration type angular velocity sensor configured as described above will be described with reference to FIGS. 2 to 4.

First, the state of the vibration type angular velocity sensor during a regular operation will be described with reference to FIG. 2. A desired driving voltage is applied to the driver units 50 arranged at both ends of each driving beam 42 to vibrate the respective driving weights 31 to 34 in the Y-axis direction based on the driving voltage.

Specifically, with respect to the driving unit 50 provided at the left end of the driving beam 42 on the upper side in FIG. 2, a tensile stress is generated by the outer piezoelectric film 51a, and a compressive stress is generated by the inner piezoelectric film 51b. Conversely, with respect to the driving unit 50 provided at the right end of the driving beam 42 on the upper side in FIG. 2, a compressive stress is generated by the outer piezoelectric film 51a and a tensile stress is generated by the inner piezoelectric film 51b. This can be realized by applying voltages in opposite phases, respectively, to the outer piezoelectric films 51a and the inner piezoelectric films 51b of the driving unit 50 arranged on the left and right ends of the upper driving beam 42 in FIG. 2.

On the other hand, with respect to the driving unit 50 provided at the left end of the driving beam 42 on the lower side in FIG. 2, a compressive stress is generated by the outer piezoelectric films 51a and a tensile stress is generated by the inner piezoelectric film 51b. Conversely, with respect to the driving unit 50 provided at the right end of the driving beam 42 on the lower side in FIG. 2, a tensile stress is generated by the outer piezoelectric films 51a, a compressive stress is generated by the inner piezoelectric films 51b This can also be realized by applying voltages in opposite phases, respectively, to the outer piezoelectric films 51a and the inner piezoelectric films 51b of the driving unit 50 arranged on the left and right ends of the lower driving beam 42 in FIG. 2.

Next, the voltage applied to each of the outer piezoelectric films 51a and the inner piezoelectric films 51b is controlled to switch the stress generated by each of the outer piezoelectric films 51a and the inner piezoelectric films 51b such that the tensile stress is switched to the compressive stress and the compressive stress is switched to the tensile stress. These operations are thereafter repeated in a predetermined drive frequency.

As a result, as shown in FIG. 2, the outer driving weight 31 and the inner driving weight 33 are vibrated in mutually opposite phases in the Y-axis direction. Further, the outer driving weight 32 and the inner driving weight 34 are vibrated in mutually opposite phases in the Y-axis direction. Further, the two inner driving weights 33 and 34 are vibrated in opposite phases in the Y-axis direction, and the two outer driving weights 31 and 32 are vibrated in opposite phases in the Y-axis direction. As a result, the vibration type angular velocity sensor is driven in the driving mode shape.

In this case, the driving beam 42 waves in an S-shape to allow the respective weights 31 to 34 to move in the Y-axis direction. However, the connection portion 43c connecting the rotation beam 43a and the driving beam 42 is a node of amplitude, that is, a fixed point, and thus is hardly displaced. When an impact or the like is applied, the supporting beams 43b are displaced and thus the respective weights 31 to 36 are allowed to move in the X-axis direction. As such, the output change due to the impact is alleviated, and the impact resistance is obtained.

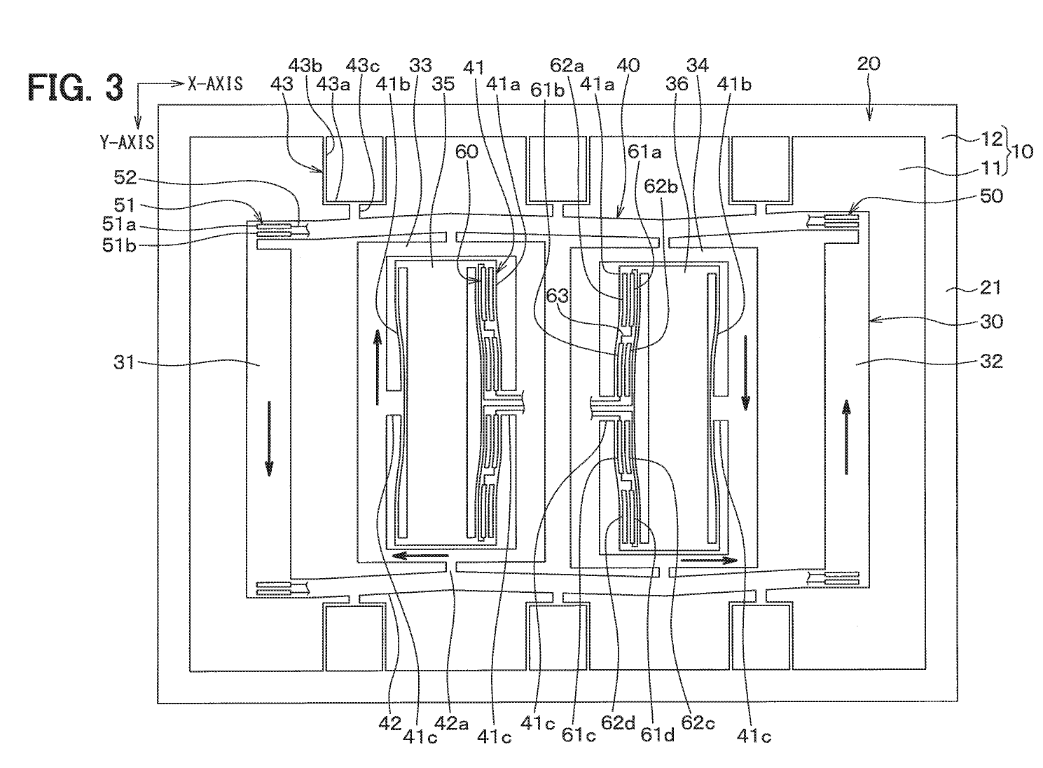

Next, a state of the vibrating angular velocity sensor when being applied with an angular velocity will be described with reference to FIG. 3. When the angular velocity around the Z-axis is applied to the vibrating angular velocity sensor during the regular operation as shown in FIG. 2, the Coriolis force causes the detection weights 35 and 36 to move in a direction intersecting the Y-axis, as shown in FIG. 3. In this case, the detection weights 35 and 36 are moved in the X-axis direction. Specifically, since the detection weights 35 and 36 and the inner driving weights 33 and 34 are connected via the detection beams 41, the detection weights 35 and 36 are displaced based on the elastic deformation of the detection beams 41. Due to the elastic deformation of the detection beam 41, the detection piezoelectric films 61a to 61d provided on the first detection beam 41a are applied with the tensile stress. Therefore, the output voltages of the detection piezoelectric films 61a to 61d change in accordance with the applied tensile stress, and these voltages are output to the outside through the detection wirings 63. By reading the output voltages, the applied angular velocity can be detected.

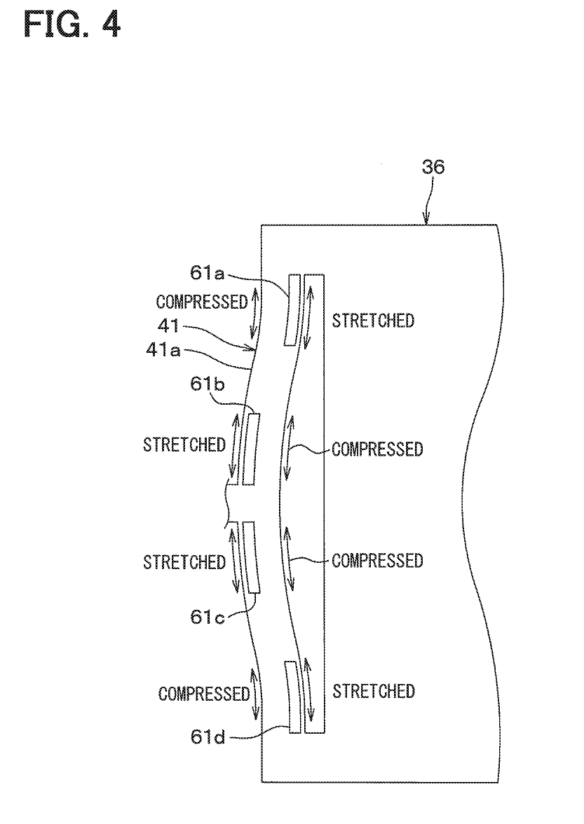

Particularly, since the detection piezoelectric films 61a to 61d are arranged in the vicinity of the connection part with the detection weights 35 and 36 and the connection part with the inner driving weights 33 and 34 in the detection beam 41, as shown in FIG. 4, the detection piezoelectric films 61a to 61d are applied with the largest tensile stress. Therefore, it is possible to further increase the output voltages of the detection piezoelectric films 61a to 61d.

In the present embodiment, since the detection beam 41 is provided by the first detection beam 41a and the second detection beam 41b having different spring constants, the following effects can be obtained.

First, the first detection beam 41a and the second detection beam 41b are configured to have different spring constants, and the dimension of the first detection beam 41a in the X-axis direction is increased larger than that of the second detection beam 41b in the X-axis direction. When the dimension of the first detection beam 41a in the X-axis direction is thus increased, the formation area of the detection piezoelectric films 61a to 61d is increased. Therefore, the change in output voltages of the detection piezoelectric films 61a to 61d with respect to the displacement of the first detection beam 41a can be increased. Therefore, the sensitivity of the vibration type angular velocity sensor can be improved.

However, if the spring constant of the first detection beam 41a is increased, there is concern that the frequency of displacement of the detection weights 35 and 36 (hereinafter referred to as detection resonance frequency), when the angular velocity is applied, is excessively increased. Therefore, the first detection beam 41a and the second detection beam 41b are configured to have different spring constants, and the dimension of the first detection beam 41a in the X-axis direction is increased while the dimension of the second detection beam 41b in the X-axis direction is reduced.

As a result, even if the spring constant of the first detection beam 41a is increased, since the spring constants of both the first detection beam 41a and the second detection beam 41b are not increased, the detection weights 35 and 36 can be kept to easily displace. Then, the detection resonance frequency can be set into a target frequency band, and thus it is less likely that the detection resonance frequency will be excessively increased.

The detection resonance frequency affects the sensitivity. For example, the sensitivity is expressed by one divided by square power of the detection resonance frequency or one divided by the detection resonance frequency. Namely, the sensitivity decreases with the increase in the detection resonance frequency. Therefore, as described above, by setting the detection resonance frequency to be in the target frequency band while suppressing from being excessively increased, even when the dimension of the first detection beam 41a in the X-axis direction is increased, the degradation in sensitivity can be restricted.

It may be considered to arrange the detection beam 41 only on one side of each detection weight 35, 36, that is, to have only the first detection beam 41a by deleting the second detection beam 41b, in order to suppress the excessive increase in the detection resonance frequency.

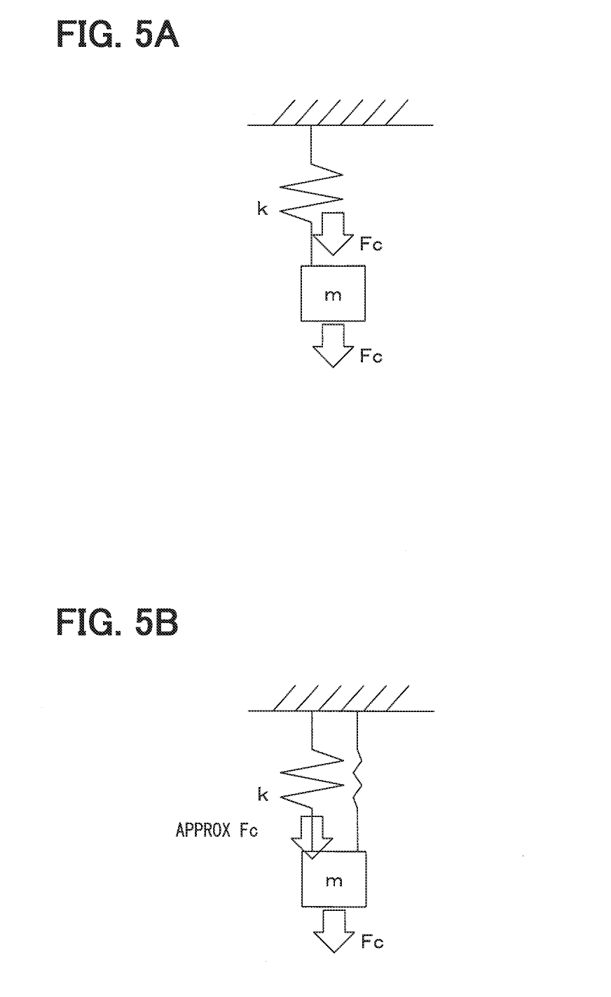

However, such a configuration is equivalent to a configuration in which the detection weight 35, 36 is held on one side, as shown in FIG. 5A. In this case, the detected resonance frequency is given by the following equation, and can be made to be in a desired frequency band. However, an unnecessary vibration mode in which the detection weights 35 and 36 perform wobbled vibration, that is, pendulum motion is generated. For this reason, it is impossible to realize a design concept of suppressing the unnecessary vibration mode. Note that in FIG. 5A and FIG. 5B, which will be described below, and in the following equations, k is a spring constant, m is the mass of the detection weights 35 and 36, and Fc is a physical quantity applied thereto.

$$f = \frac{1}{2} π \sqrt{\frac{k}{m}} \qquad [ Equation 1 ]$$

On the other hand, in the present embodiment, the detection beam 41 includes the second detection beam 41b the dimension of which in the X-axis direction is suppressed while keeping the dimension of the first detection beam 41a in the X-direction to be large. Therefore, as shown in FIG. 5B, the detection beam 41 can have a configuration equivalent to a double-side supporting structure in which the detection weights 35, and 36 are supported at both sides. Thereby, it is possible to suppress the generation of the unnecessary vibration mode of the detection weights 35 and 36, such as wobbled vibrations. The spring constant of the second detection beam 41b is smaller than the spring constant of the first detection beam 41a. Therefore, the detection resonance frequency is determined substantially based on the spring constant of the first detection beam 41a, and the influence of the spring constant of the second detection beam 41b can be reduced. As such, the detection beam 41 substantially has the detection resonance frequency given by the above-mentioned equation 1. Therefore, as described above, it is possible to suppress the detection resonance frequency from being excessively increased, and to be set into the target frequency band.

As described above, in the present embodiment, the first detection beam 41a and the second detection beam 41b supporting the detection weight 35, 36 have different spring constants. Further, the dimension of one of the first detection beam 41a and the second detection beam 41b in the X-axis direction is increased so as to increase the formation area of the detection piezoelectric films 61a to 61d, to thereby improve the sensitivity, whereas the dimension of the other of the first detection beam 41a and the second detection beam 41b is reduced so as to suppress the increase in the detection resonance frequency. Accordingly, it is possible to improve the sensitivity.

### Other Embodiments

While the present disclosure has been described with reference to the embodiment, it is to be understood that the disclosure is not limited to the embodiment described above. The present disclosure is intended to cover various modification and equivalent arrangements. In addition, while the various combinations and configurations, other combinations and configurations, including more, less or only a single element, are also within the spirit and scope of the present disclosure.

(1) In the above-described embodiment, the first detection beam 41a and the second detection beam 41b are made of the same material, but are differentiated in the dimensions in the X-axis direction so as to have the different spring constants. However, such a configuration is merely an example for making the spring constant of the first detection beam 41a and the second detection beam 41b different from each other, and other configurations are also acceptable.

For example, the first detection beam 41a and the second detection beam 41b may be made of different materials, that is, made of different materials different in rigidity, so as to have the different spring constants. In this case, for example, the second detection beam 41b has the rigidity higher than that of the first detection beam 41a, and the width of the first detection beam 41a is larger than the width of the second detection beam 41b. Further, the detection piezoelectric films 61a to 61b are formed on the first detection beam 41a. Further, the width of the first detection beam 41a and the width of the second detection beam 41b can be the same. That is, by making the second detection beam 41b of the material having lower rigidity than the first detection beam 41a, the widths of the first detection beam 41a and the second detection beam 41b can be increased, as compared with a case in which the second detection beam 41b is also made of a material having high rigidity as the first detection beam 41a. Therefore, it is possible to substantially increase the formation area for the piezoelectric film. As a result, it is possible to improve the sensitivity. In this case, the detection piezoelectric films 61a to 61d may be provided on any of the first detection beam 41a and the second detection beam 41b.

Further, the spring constants of the first detection beam 41a and the second detection beam 41b may be differentiated by differentiating the dimensions of the first detection beam 41a and the second detection beam 41b in the direction normal to the XY plane, that is, in the direction normal to a plane including the movement trajectories of the detection weights 35 and 36. For example, by making the dimension of the first detection beam 41a larger than the dimension of the second detection beam 41b in this direction, the spring constant of the first detection beam 41a is made larger than that of the second detection beam 41b.

(2) In the above-described embodiment, the detection beam 41 is disposed on both sides of each detection weight 35, 36 in the X-axis direction. Alternatively, the two detection beams 41 may be provided on the sides of the detection weight 35, 36 at positions different in the X-axis direction, and be connected to inner walls of the inner driving weight 33, 34.

(3) In the above embodiment, the case where the SOI substrate is used as the substrate 10 has been described. However, the SOI substrate is an example of the substrate 10, and a substrate other than the SOI substrate may be used.

(4) The present disclosure is not limited to a paired angular velocity detection structure having two outer driving weights 31 and 32, two inner driving weights 33 and 34, and two detection weights 35 and 36. The present disclosure can also be applied to a vibration type angular velocity sensor having more than two angular velocity detection structures.

(5) Although the angular velocity sensor has been described as an example of the physical quantity sensor, the present disclosure can also be applied to other physical quantity sensors. For example, the present disclosure can also be applied to an acceleration sensor that has a sensor structure body supporting a detection weight with a detection beam so that the detection weight moves in accordance with an application of acceleration, and the detection beam displaces with the detection weight, to thereby detect the acceleration applied. The present disclosure can also be applied to a tensile force sensor or the like in which a material as a target of strength detection to a detection weight supported by a detection beam, and that detects a tensile load, when the material is broken by application of the tensile load to the material, based on strain of the detection beam.

1. A physical quantity sensor comprising
a substrate;
a beam part that includes a detection beam;
a detection weight that is supported to the substrate through the beam part;
a detection piezoelectric film that is disposed on the detection beam and is configured to generate an electric output according to displacement of the detection beam caused by movement of the detection weight in a direction due to an application of a physical quantity, wherein
the detection beam includes a first detection beam and a second detection beam that are disposed to hold the detection weight at different positions from each other in the direction,
the first detection beam and the second detection beam have different spring constants, and
the detection piezoelectric film is disposed on the first detection beam.

2. The physical quantity sensor according to claim 1, wherein
the first detection beam has a larger dimension than the second detection beam in the direction to have the spring constant larger than that of the second detection beam.

3. The physical quantity sensor according to claim 1, wherein
the first detection beam and the second detection beam are made of different materials to have the different spring constants.

4. The physical quantity sensor according to claim 1, wherein
the first detection beam and the second detection beam have different dimensions in a direction normal to a plane including a trajectory of the movement of the detection weight to have the different spring constants.

5. A vibration type angular velocity sensor for detecting an angular velocity, comprising the physical quantity sensor according to claim 1, wherein
the physical quantity sensor further includes a driving weight supported to the substrate through a supporting beam,
the detection weight is supported to the driving weight through the first detection beam and the second detection beam,
when the angular velocity as the physical quantity is applied while the driving weight is being driven and vibrated, the detection weight moves and the first and second detection beams displace in accordance with the angular quantity, and
the detection piezoelectric film is configured to output a voltage as the electric output indicative of displacement of the first detection beam and the second detection beam.

6. A vibration type angular velocity sensor for detecting an angular velocity, comprising the physical quantity sensor according to claim 1, wherein
the physical quantity sensor further includes two detection weights as a pair,
the physical quantity sensor further includes a driving weight that has a pair of inner driving weights and a pair of outer driving weights,
each of the pair of inner driving weights has a shape surrounding a corresponding one of the two detection weights, and connects to the corresponding one of the two detection weights through the first detection beam and the second detection beam,
the pair of outer driving weights is disposed on opposite sides of the pair of inner driving weights,
the beam part includes a driving beam connecting the inner driving weights and the outer driving weights,
the outer driving weights and the inner driving weights to which the detection weights are connected are supported to the substrate through a supporting member including a support beam,
the physical quantity sensor further includes a drive unit that vibrates the inner driving weights and the outer driving weights in opposite directions, wherein
the drive unit is configured to drive and vibrate the outer driving weights and the inner driving weights by deforming the driving beam, and
when the angular velocity as the physical quantity is applied during driving and vibrating, the detection beam is displaced and the detection weights are moved in directions intersecting with a direction of vibration of the inner driving weights to change an output voltage of the detection piezoelectric films so that the angular velocity is detected.
